(19) United States
(12) Patent Application Publication
(10) Pub. No.: US 2026/0369443 A1
(43) Pub. Date: Nov. 19, 2026

(54) Superconducting Quantum Computing Apparatus

(71) Applicant: YEDA RESEARCH AND DEVELOPMENT CO. LTD., Rehovot (IL)

(72) Inventors: Serge Rosenblum, Rehovot (IL); Engin Çiftyürek, Istanbul (TR); Peter Vom Stein, Bergisch Gladbach (DE); Ofir Milul, Kibutz Hasolelim (IL); Barkay Guttel, Jerusalem (IL)

(21) Appl. No.: 19/153,973

(22) PCT Filed: Jan. 25, 2024
(86) PCT No.: PCT/IB2024/050687

§ 371 Date: Aug. 6, 2025

Related U.S. Application Data
(60) Provisional application No. 63/445,065, filed on Feb. 13, 2023.
(60) Provisional application No. 63/508,914, filed on Jun. 19, 2023.

(51) Int. Cl. G21K 1/30; H10N 60/12

(52) U.S. Cl. CPC G21K 1/30; H10N 60/12

(57) ABSTRACT

Apparatus for quantum computing, consisting of a superconducting shell (50) having a first surface of rotation (66) about a central axis (54), and a second surface of rotation (86), different from the first surface of rotation, about the central axis. The first surface terminates in a first rim (78), and the second surface has an aperture (90) and terminates in a second rim (102) congruent to the first rim. The first rim and the second rim are sealed together to enclose a microwave cavity (14A) within the shell. The apparatus further includes a superconducting qubit (12) formed on a substrate (16) which is mounted so that a portion of the substrate penetrates through the aperture, thereby coupling the superconducting qubit to the microwave cavity.

### CROSS-REFERENCE TO RELATED APPLICATIONS

This application claims the benefit of U.S. Provisional Patent Application 63/445,065, filed Feb. 13, 2023, and U.S. Provisional Patent Application 63/508,914, filed Jun. 19, 2023, which are incorporated herein by reference.

### FIELD OF THE INVENTION

This disclosure relates generally to computing, and specifically to quantum computing.

### BACKGROUND OF THE INVENTION

A quantum computer is a computer that exploits quantum mechanical phenomena. The basic unit of information in quantum computing is the qubit, similar to the bit in traditional digital electronics, but unlike a classical bit, a qubit can exist in a superposition of its two computational “basis” states. However, physically engineering high-quality qubits has proven challenging. If a physical qubit is not sufficiently isolated from its environment, it suffers from quantum decoherence, introducing noise into calculations.

### SUMMARY OF THE INVENTION

An embodiment of the present invention provides apparatus for quantum computing, including:
a superconducting shell having a first surface of rotation about a central axis, and a second surface of rotation, different from the first surface of rotation, about the central axis, the first surface terminating in a first rim, the second surface having an aperture and terminating in a second rim congruent to the first rim, the first rim and the second rim being sealed together to enclose a microwave cavity within the shell; and
a superconducting qubit formed on a substrate, which is mounted so that a portion of the substrate penetrates through the aperture, thereby coupling the superconducting qubit to the microwave cavity.

Typically, at least a portion of the first surface of rotation is curved, so that all points on the at least portion have a finite radius of curvature. The at least portion of the first surface may terminate in the first rim and in a third rim, and a first tangent plane to a first given point on the first rim may be parallel to the central axis, and a second tangent plane to a second given point on the third rim may be normal to the central axis.

In a disclosed embodiment at least a portion of the first surface of rotation is planar, so that all points on the at least portion have an infinite radius of curvature. The at least portion may lie in a plane normal to the central axis.

In a further disclosed embodiment the first surface of rotation includes a planar surface and a curved surface, and a first area of the planar surface is smaller than a second area of the curved surface. The curved surface may surround and be contiguous with the planar surface.

In a yet further disclosed embodiment the apparatus includes a further aperture inserted into the first surface of rotation.

In an alternative embodiment the first surface of rotation and the second surface of rotation are shaped and dimensioned so that the cavity resonates at a selected microwave frequency, and so that an electric field of microwaves resonating at the selected microwave frequency is a maximum in proximity to the aperture.

In a further alternative embodiment the aperture lies on the central axis.

In a yet further alternative embodiment an edge of the substrate lies between a first plane defined by the first rim and second plane, normal to the central axis, containing a point where the aperture cuts the central axis.

In another embodiment at least a portion of the second surface is planar, so that all points on the at least portion have an infinite radius of curvature. The at least portion may lie in a plane normal to the central axis.

Typically, at least a portion of the second surface is curved, so that all points on the at least portion have a finite radius of curvature.

In another disclosed embodiment the superconducting qubit consists of one of a transmon, a fluxonium, a flux qubit, and a Superconducting Nonlinear Asymmetric Inductive eLement (SNAIL) qubit.

Typically, the first rim and the second rim are sealed together by electron beam welding.

In another disclosed embodiment the substrate is formed from one of silicon and sapphire.

The shell may be formed from one of niobium, aluminum, titanium, and tantalum.

In another disclosed embodiment the first surface has a first opening centered on the central axis, and the superconducting shell further includes:
at least one more microwave cavity therein, the at least one more microwave cavity consisting of a given cavity having a second opening connected to the first opening so as to couple the microwave cavity and the at least one more microwave cavity.

The microwave cavity and the at least one more microwave cavity may be configured to resonate in a number of fundamental transverse magnetic modes equal to a cardinality of the microwave cavity and the at least one more microwave cavity.

A difference in frequencies of resonance of the fundamental transverse magnetic modes may be less than a coupling between the modes.

In a yet further disclosed embodiment the superconducting qubit is configured to encode a number of computational qubits to the microwave cavity and the at least one more microwave cavity, wherein the number of computational qubits is equal to a cardinality of the microwave cavity and the at least one more microwave cavity.

There is further provided, according to an embodiment of the present invention, a method for quantum computing, including:
providing a superconducting shell;
forming within the superconducting shell a first surface of rotation about a central axis, and a second surface of rotation, different from the first surface of rotation, about the central axis, the first surface terminating in a first rim, the second surface having an aperture and terminating in a second rim congruent to the first rim, the first rim and the second rim being sealed together to enclose a microwave cavity within the shell;
forming a superconducting qubit on a substrate; and
mounting the substrate so that a portion thereof penetrates through the aperture, thereby coupling the superconducting qubit to the microwave cavity.

The present disclosure will be more fully understood from the following detailed description of the embodiments thereof, taken together with the drawings, in which:

### BRIEF DESCRIPTION OF THE DRAWINGS

FIGS. 1A, 1B, and 1C are schematic figures of an apparatus for quantum computing, according to an embodiment of the present invention;

FIG. 1D is a schematic drawing of the surfaces of a cavity when the cavity is cut by a yz plane, according to an embodiment of the present invention;

FIG. 1E is a schematic figure illustrating a two-dimensional curve, according to an embodiment of the present invention;

FIG. 2 is a schematic sectional illustration of elements of an apparatus for quantum computing, according to an alternative embodiment of the present invention;

FIG. 3 is a schematic sectional illustration of elements of an apparatus for quantum computing, according to a further alternative embodiment of the present invention;

FIG. 4 is a schematic sectional illustration of elements of an apparatus for quantum computing, according to a yet further alternative embodiment of the present invention;

FIG. 5 is a schematic sectional illustration of elements of an apparatus for quantum computing, according to an alternative embodiment of the present invention; and

FIG. 6 is a schematic sectional illustration of elements of an apparatus for quantum computing, according to an alternative embodiment of the present invention.

### DETAILED DESCRIPTION OF EMBODIMENTS

### Overview

A superconducting qubit, for example, in the form of a transmon, is a modality used to store and process information used in quantum computing. However, the use of a transmon for quantum computing is limited at present by the short coherence time of the qubit generated by the transmon. Embodiments of the present invention address this problem by coupling the transmon to a cavity-system comprising one or more cavities. The cavity-system has a high quality factor (Q), and the coupling of the transmon to the system is configured to have a minimal effect on the Q factor of the cavity-system. The transmon-cavity-system combination enables high-fidelity mapping of quantum information between the cavity-system and the transmon, while providing long coherence times for the photons. The combination may be used as a superconducting quantum memory for a plurality of qubits, and/or as a single superconducting computational qubit.

In one disclosed embodiment the cavity-system comprises a single cavity formed from a shell having two sections, each section having a respective surface of rotation about a common axis, the two surfaces of rotation being different. Each surface terminates in a respective rim, the two rims being configured to be congruent to each other, and the two rims are sealed together so as to enclose the cavity. The common axis thus acts as an axis of symmetry for the cavity.

One of the surfaces of the single cavity has an aperture that acts as a waveguide and that is used to couple the transmon to the cavity. The transmon is formed on a substrate, and the substrate is mounted so that a portion of the substrate penetrates through the aperture thereby coupling the transmon to the cavity. In the following description the single cavity is also referred to as the transmon-connecting cavity, or just as the connecting cavity.

The two surfaces are selected so that the connecting cavity formed by the surfaces has a low filling factor, and so that when the cavity resonates, in a selected mode of resonance, the electric field at or near the aperture is high. By configuring the electric field at the aperture to be high, the coupling of the transmon to the connecting cavity may be high with minimal penetration of the substrate into the cavity, thereby preventing degradation of the cavity Q factor due to imperfections related to the substrate.

In one embodiment one of the surfaces of the connecting cavity is generally cup-shaped, and the second surface of the cavity is generally planar. Operating the cavity in a fundamental transverse magnetic mode of resonance causes the electric field to be a maximum at or near the center of the planar surface, and this is the location where the axis of symmetry of the connecting cavity cuts the surface. By forming the aperture in the second surface at this central location, the transmon substrate may be inserted through the aperture by an amount that does not substantively reduce the Q of the connecting cavity, but that does provide sufficient coupling to enable high-fidelity operations between the transmon and the cavity.

In another disclosed embodiment, the cavity-system comprises a plurality of linked cavities, one of which corresponds to the transmon-connecting cavity described above. The other cavities are linked, either by an iris opening between adjacent cavities, or by a waveguide connecting adjacent cavities, and because they do not need to couple to a transmon, the other cavities may have a higher Q than the transmon-connecting cavity. Thus, in a cavity-system comprising two cavities, one cavity is a transmon-connecting cavity, and the other cavity is a higher-Q cavity, so that the overall Q of the two cavity system is larger than that of the single cavity system, i.e. the transmon-connecting cavity.

In addition, and in contrast to the transmon-connecting cavity, which supports one fundamental mode of resonance of photons in the cavity, a cavity-system comprising a plurality of cavities supports multiple fundamental modes of resonance, the number of modes being equal to the number of cavities. Thus a transmon-cavity-system combination having a plurality of cavities has a larger capacity to encode quantum information. While the single transmon-connecting cavity, coupled to the transmon, may be used to encode one computational qubit, N cavities coupled to the transmon may be used to encode N computational qubits in the N fundamental modes, where N is a natural number.

### System Description

In the following description, like elements in the drawings are identified by like numerals, and like elements are differentiated as necessary by appending a letter to the identifying numeral.

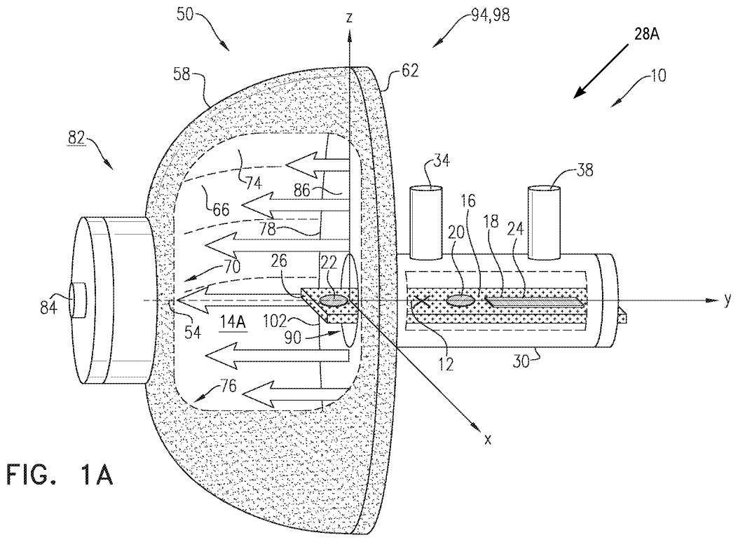

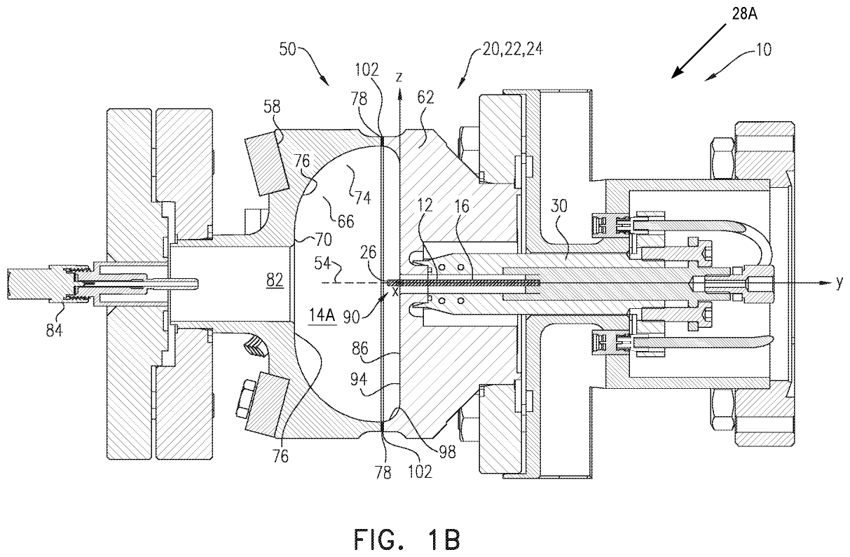

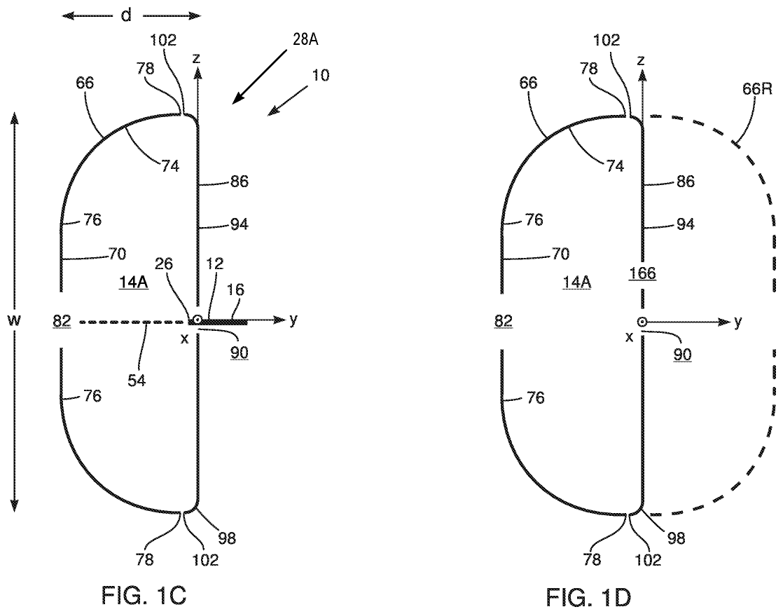

Reference is now made to FIGS. 1A, 1B, and 1C, which are schematic figures of an apparatus 10 for quantum computing, according to an embodiment of the present invention. FIG. 1A is a schematic cut-away perspective view of the apparatus, FIG. 1B is a schematic cross-sectional view of the apparatus, and FIG. 1C is a schematic sectional illustration of selected elements of the apparatus. As is described further below, apparatus 10 may be used as a superconducting computational qubit, and/or as a superconducting quantum memory for a plurality of qubits, and apparatus 10 is also referred to herein as memory 10. Memory 10 is typically operated at a temperature of approximately 10 mK, and to mitigate adverse effects on the coherence time of photons used in the memory, the memory is typically operated within a mu-metal container (not shown in the figures) so as to prevent any changes in an external magnetic field from affecting the memory. For clarity in the description of memory 10, FIGS. 1A-1C have been drawn on a set of xyz Cartesian axes, and the location and orientation of the axes with respect to memory 10 are described further below.

As is illustrated in the figures, memory 10 comprises a superconducting qubit 12 coupled to a microwave cavity 14A, also termed qubit-connecting-cavity 14A, or just connecting cavity 14A. As is explained later, embodiments of the present invention comprise a qubit such as qubit 12 coupled to a cavity system comprising one or more cavities. In FIGS. 1A, 1B, and 1C, qubit 12 is coupled to a single cavity, connecting cavity 14A, which comprises the single cavity of a single cavity system 28A. Other single cavity systems 28B, 28C, and 28D are described below. Other cavity systems having more than one cavity that are comprised in embodiments of the present invention are also described below.

In the following description, for simplicity and clarity superconducting qubit 12 is assumed to comprise a transmon, and is also referred to herein as transmon 12. Those having ordinary skill in the art will be able to adapt the description, mutatis mutandis, for other superconducting qubits, such as, but not limited to, a fluxonium, a flux qubit, and a Superconducting Nonlinear Asymmetric Inductive eLement (SNAIL) qubit, and all such qubits are assumed to be comprised within the scope of the present invention.

Transmon 12 may be formed on a dielectric substrate 16, and in the embodiment depicted in the figures the substrate is assumed to comprise a non-square rectangular chip of sapphire, also referred to herein as chip 16, and a portion of the chip is configured to penetrate into the cavity. While the description herein assumes that substrate 16 is in the form of a rectangular chip on sapphire, it will be understood that the substrate may have other shapes, and may be formed of other suitable materials, such as silicon, all of which are comprised within the scope of the present invention, and those having ordinary skill in the art will be able to adapt the description, mutatis mutandis, for such other shapes and materials. The xyz Cartesian axes of the figures have been drawn with the origin of the axes on a surface 18 of rectangular chip 16, with the x- and y-axes parallel to the sides of the chip, and with the z-axis normal to surface 18. The location of the origin of the coordinates is also described below.

Formed on chip 16 is a Josephson Junction 20 connected in parallel to a capacitor 22, the connected combination acting as transmon 12. Chip 16 is housed within a waveguide 30, and also formed on chip 16 is a stripline resonator 24 which is coupled to transmon 12 via the waveguide. Waveguide 30 comprises a first port 34, which is configured to act as a microwave conduit directed to transmon 12, and the transmon may be energized by transmitting a microwave pulse to the transmon via port 34. Waveguide 30 may also comprise a second port 38 that is configured to act as a microwave conduit directed to resonator 24. Port 38 may be used to transmit microwaves to and from resonator 24, enabling measurements to be made on transmon 12 and cavity 14A.

Connecting cavity 14A is fashioned from a superconducting shell 50, formed, by way of example, of niobium, the cavity being formed internally within the shell, and having a central axis 54, described further below. Shell 50 may be formed from suitable superconductors other than niobium, such as aluminum, titanium, or tantalum, and all such superconductors are assumed to be comprised within the scope of the present invention. Shell 50 is in two connected sections, a first superconducting shell section 58, and a second superconducting shell section 62.

First shell section 58 has a generally cup-shaped surface 66 which is a surface of rotation about central axis 54, and it will be understood that since surface 66 is a surface of rotation about the central axis, the central axis is also an axis of symmetry of the surface, which is herein also termed first surface 66. In the figures, the y-axis has been drawn to be coincident with central axis 54.

In some embodiments, such as the embodiment illustrated in the figures, first surface 66 is comprised of two contiguous regions: a central circular planar region 70, and a curved region 74 surrounding the planar region.

Circular planar region 70 comprises a two-dimensional (2D) plane surface normal to and centered on the central axis, i.e., to the y-axis, and all points on the surface have an infinite radius of curvature. Planar region 70 is also termed planar surface 70.

Curved region 74 is a three-dimensional (3D) surface formed by rotating a 2D curve about central axis 54. In contrast to planar region 70, all points on the surface of curved region 74 have a finite radius of curvature. An example of an expression for the 2D curve is provided below. Curved region 74 is also termed curved surface 74. In the embodiment illustrated in the figures, the surface area of planar region 70 is less than the surface area of curved region 74. In an alternative embodiment, the surface area of planar region 70 is greater than or equal to the surface area of curved region 74. Curved region 74 initiates at an internal edge 76, touching planar region 70, and terminates in an external edge 78, herein also termed a rim 78, which lies in a 2D plane normal to central axis 54. Rim 78 is circular and has central axis 54 as an axis of symmetry.

Curved surface 74 may be configured so that a tangent plane at any point on internal edge 76 is normal to central axis 54, and so that a tangent plane at any point on external edge 78 is parallel to the central axis.

Some embodiments may have an aperture 82 provided in first surface 66, for example in planar region 70, as is illustrated in the figures. Cavity 14A may be characterized using aperture 82, for example by inserting an undercoupled cavity pin 84 into the aperture, and using the pin to perform ring-down measurements on the cavity so as to quantify the cavity Q value.

Second shell section 62 has a generally planar surface 86 which is also a surface of rotation about central axis 54, so that the central axis is also an axis of symmetry of surface 86, which is herein also termed second surface 86. As is illustrated in the figures, the surface of rotation of second surface 86 is different from the surface of rotation of first surface 66.

Second surface 86 has an aperture 90 located centrally in the surface, at the position where the surface cuts central axis 54, and substrate 16 penetrates the aperture. Aperture 90 connects waveguide 30 to cavity 14A, and the aperture also acts as a waveguide, conveying microwave photons between cavity 14A and transmon 12.

In some embodiments, such as the embodiment illustrated in the figures, second surface 86 is comprised of two contiguous regions: a central circular planar region 94, and a curved region 98 surrounding the planar region. Planar region 94 is formed as a plane surface of rotation that is normal to central axis 54. Since second surface 86 is generally planar, the surface area of central planar region 94 is typically greater than the surface area of curved region 98. In one embodiment the ratio of the planar surface area to the curved surface area is approximately ⅔, but in other embodiments the ratio may be larger or smaller than ⅔.

Second surface 86 terminates in an external edge 102, also termed a rim 102. As for rim 78, rim 102 is circular and lies in a 2D plane normal to central axis 54, and the central axis as an axis of symmetry for rim 102.

Referring to FIG. 1C, the figure shows cavity surfaces 66 and 86, and transmon 12, as they appear when cut by the yz plane. In the figure, for clarity, surfaces 66 and 86, which are sealed together as described below when cavity 14A is formed, are shown separated. Surfaces 66 and 86 constitute the surfaces forming cavity 14A.

In forming cavity 14A, rim 78 of first section 58 and rim 102 of second section 62 are configured to be congruent. In addition, as explained above, curved region 74 of the first section may be configured so that for any point on rim 78, a tangent plane at the point is parallel to the central axis. Furthermore, in the disclosed embodiment curved region 98 of the second section may be configured so that for any point on rim 102, a tangent plane at the point is parallel to the central axis.

To construct cavity 14A, rims 78 and 102 are sealed together, for example by electron-beam welding. It will be understood that because the directions of the tangents to rims 78 and 102 are both parallel to the central axis, the surface of the cavity at the joined rims is smooth.

As stated above, in apparatus 10 a portion of substrate 16 is configured to penetrate through aperture 90 into cavity 14A. In an embodiment, the penetration is configured so that a leading edge 26 of substrate 16 (in the figure edge 26 is an edge of the substrate having the most negative y-value) lies between a plane defined by rim 78 and a plane, normal to the central axis, containing a point where aperture 90 cuts the central axis. In the figures the origin of the xyz set of coordinates is set to correspond to this point.

In an exemplary embodiment, cavity 14A has a width, w, approximately equal to 59 mm, and a depth, d, approximately equal to 22 mm (FIG. 1C). The cavity resonates in the TM₀₁₀ mode at an approximate frequency of 4.3 GHZ, and has a quality factor Q approximately equal to 3×10⁹. Schematic electric field lines for cavity 14A are shown as arrowed lines in the cavity in FIG. 1A. The inventors have used a finite element simulation to determine that such a cavity has a filling factor of approximately 1.4×10⁻⁸. In the exemplary embodiment transmon 12 has a resonant frequency approximately equal to 3.1 GHz and substrate 16 may be inserted into aperture 90 so that the substrate extends into cavity 14A by approximately 1 mm. It will be understood that the dimensions and measurements for cavity 14A cited herein are purely by way of example, and do not limit the scope of the present invention.

As stated above, apparatus 10 comprises connecting cavity 14A, which is a single cavity of cavity system 28A.

Reference is now made to FIG. 1D, which is a schematic drawing of the surfaces of cavity 14A when the cavity is cut by the yz plane. Cavity 14A is dimensioned so that using the microwaves produced by transmon 12 and injected into the cavity through aperture 90 the cavity resonates in a TM₀₁₀ mode, i.e., the fundamental transverse magnetic (TM) mode. The shape of surface 66 is selected so that the filling factor for a theoretical cavity 166 formed by surface 66 combined with a reflection 66R of surface 66 in the xz plane is as small as possible.

Resonating in the TM₀₁₀ mode, theoretical cavity 166 has a maximum electric field at the center of the cavity, i.e., at the origin of the xyz coordinates. However, introducing a transmon such as transmon 12 to the center, on substrate 16, so as to have effective coupling of the transmon to the cavity, significantly increases the filling factor of theoretical cavity 166.

Introducing a generally planar surface such as surface 86 increases the filling factor of the cavity formed, cavity 14A, compared to the filling factor of theoretical cavity 166. However, the planarity of surface 86 reflects the electric field of the cavity 14A when resonating, so that the maximum electric field remains at the origin of the xyz coordinates. Thus, as applies to embodiments of the present invention, forming an aperture such as aperture 90 at the center of surface 86, so that the maximum electric field of the cavity is proximate to the aperture, enables a small portion of substrate 16 to be inserted into cavity 14A, with minimal further increase of the filling factor, while allowing good coupling of the transmon to the cavity.

In apparatus 10 microwave photons may be encoded from transmon 12 into cavity 14A, for storage therein, by injecting an appropriate sideband drive frequency to the transmon via first port 34. The sideband drive frequency may then be injected at a later time to recover the stored photons. Measurements on transmon 12, to determine the states of the recovered photons, may be made via second port 38 and resonator 24. It will be understood that using ports 34 and 38 apparatus 10 may be used as either a memory or as a computational qubit.

The inventors have used the exemplary embodiment described above to simultaneously store, and then recover, more than 1000 photons having different states.

Reference is now made to FIG. 1E, which is a schematic figure illustrating a 2D curve, according to an embodiment of the present invention. As stated above, 3D curved surface 74 is formed by rotating a 2D curve about central axis 54. In the figure, a curve 106 has been drawn on an arbitrary set of yz axes, and the curve may be translated as necessary, before being rotated about an axis such as central axis 54, to form a surface of rotation corresponding to curved surface 74.

An example of an expression for the 2D curve is given by equation (1):

$$\frac{\vert {y}^{n} \vert}{{a}^{n}} + \frac{\vert {z}^{n} \vert}{{b}^{n}} = 1 ; - a \leq y \leq 0 , 0 \leq z \leq b , n \geq 2 \qquad ( 1 )$$

where a, b, and n are positive rational numbers.

The 2D curve generated by expression (1) is a monotonic arc that is a section of a curve herein termed a quasi-ellipse; if n is 2, then the 2D curve is a monotonic section of an ellipse. Curve 106 is also referred to herein as arc 106.

Arc 106 has a lower point 106L and an upper point 106U, and these points, when the surface described above is formed by rotation of the arc about central axis 54, respectively generate a first circular edge or rim and a second circular edge or rim. It will be understood, from inspection of equation (1), that a tangent plane to a point on the first circular edge is normal to central axis 54, and that a tangent plane to a point on the second circular edge is parallel to the axis, corresponding to the properties of edges 78 and 102 of curved surface 74.

Other 2D arcs, which when rotated generate a surface having the same tangential properties as those described above for arc 130, will be apparent to those having ordinary skill in the art, and all such arcs are considered to be comprised within the scope of the present invention.

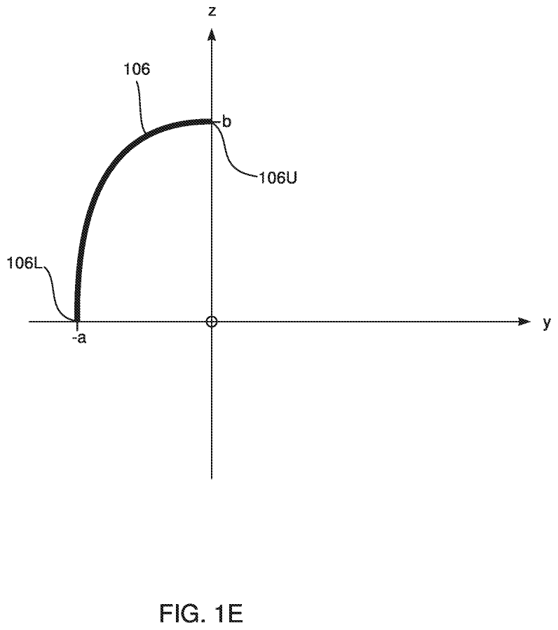

FIG. 2 is a schematic sectional illustration of elements of an apparatus 110 for quantum computing, according to an alternative embodiment of the present invention. Apart from the differences described below, the operation of apparatus 110 is generally similar to that apparatus 10 (FIGS. 1A, 1B and 1C), and elements indicated by the same reference numerals in apparatus 10 and 110 are generally similar in construction and in operation.

FIG. 2 shows cavity surfaces and transmon 12 of apparatus 110, as they appear when cut by the yz plane.

In contrast to apparatus 10, in apparatus 110 there is no aperture 82. Rather, a first surface 66A, comprising a central circular planar region 70A and a curved region 74A surrounding the planar region, is a continuous unbroken surface. First surface 66A, planar region 70A, and curved region 74A are respectively substantially similar to first surface 66, planar region 70, and curved region 74, apart from the absence of aperture 82 in planar region 70A. Except for the differences in the surfaces described above, a connecting cavity 14B has substantially similar structure and substantially similar properties to those of connecting cavity 14A, being formed from the surfaces, surface 66A and surface 86, of two connected shell sections.

As for apparatus 10, apparatus 110 comprises a single connecting cavity, connecting cavity 14B, which is the single cavity of a single cavity system 28B.

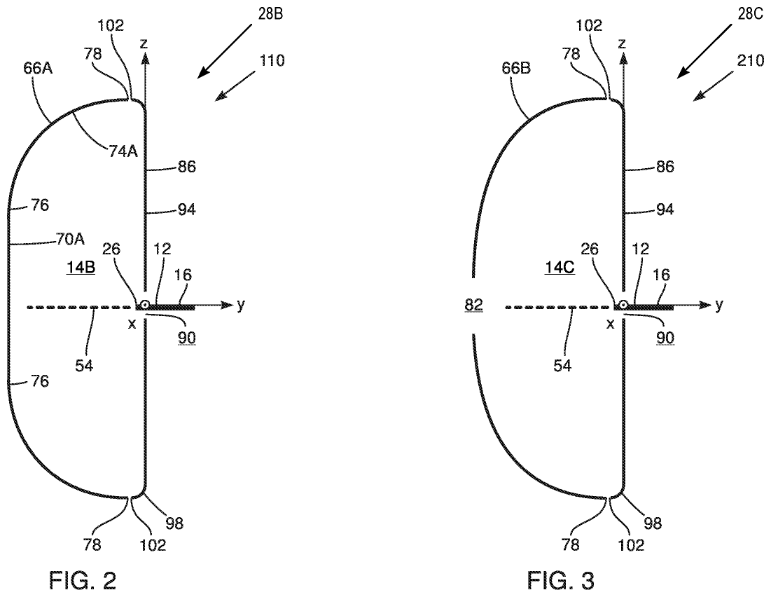

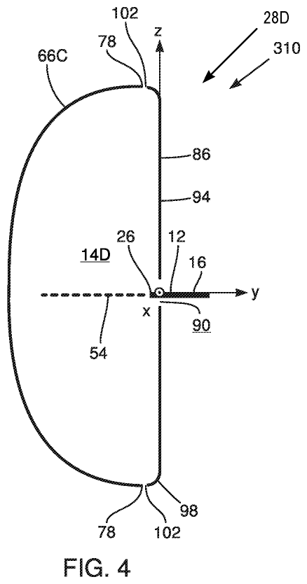

FIGS. 3 and 4 are respective schematic sectional illustrations of elements of an apparatus 210 and an apparatus 310 for quantum computing, according to further alternative embodiments of the present invention. Apart from the differences described below, the operation of apparatus 210 and of apparatus 310 is generally similar to that of apparatus 10, and elements indicated by the same reference numerals in apparatus 10, 210 and 310 are generally similar in construction and in operation.

FIG. 3 and FIG. 4 show cavity surfaces and transmon 12, as they appear in apparatus 210 and 310, when cut by the yz plane.

In contrast to apparatus 10, in a first surface 66B in apparatus 210 and in a first surface 66C in apparatus 310 there is no central planar region. Rather, both surface 66B and surface 66C are curved, so that all points on the surfaces have a finite radius of curvature, and both are produced by rotating a curve such as that given by equation (1) about a central axis. The difference between the two surfaces is that aperture 82 is present in surface 66B, and absent in surface 66C. Except for the differences in the surfaces described above, a connecting cavity 14C (FIG. 3) and a connecting cavity 14D (FIG. 4) have substantially similar structure and substantially similar properties to those of connecting cavity 14A, being formed from the surfaces of two connected shell sections.

Both apparatus 210 and apparatus 310 comprise a single cavity system: a single cavity system 28C for apparatus 210, and a single cavity system 28D for apparatus 310.

In some embodiments of apparatus 210 and 310 curved section 98 is not present in second surface 86, so that the second surface is planar and is directly connected to the respective first surface.

The embodiments described above, i.e., apparatus 10, 110, 210 and 310, are examples of the present disclosure using a single cavity system. The following sections of the disclosure describe embodiments of the present invention wherein the apparatus uses a cavity system having more than one cavity.

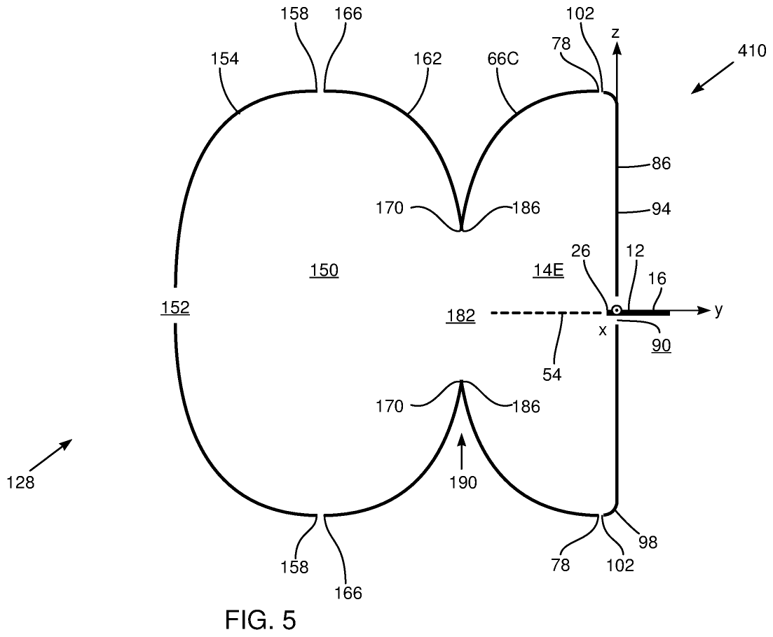

FIG. 5 is a schematic sectional illustration of elements of an apparatus 410 for quantum computing, according to an alternative embodiment of the present invention. Apart from the differences described below, the operation of apparatus 410 is generally similar to that of apparatus 310 (FIG. 4), and elements indicated by the same reference numerals in apparatus 310 and apparatus 410 are generally similar in construction and in operation.

FIG. 5 shows cavity surfaces and transmon 12 of apparatus 410, as they appear when cut by the yz plane.

In contrast to apparatus 310, and as illustrated in the figure, apparatus 410 comprises two coupled cavities. The two coupled cavities comprise a first cavity 14E, which except as described below is substantially similar to cavity 14D (FIG. 4), and a second cavity 150. The two coupled cavities forming a dual cavity system 128.

Cavity 14E, unlike cavity 14D, comprises a circular opening 182, orthogonal to and symmetrical about axis 54, in surface 66C. Thus, surface 66C terminates in an internal circular rim 186 surrounding opening 182, as well as in rim 78, herein termed external rim 78.

Cavity 150, as for cavity 14E is formed from surfaces of rotation about axis 54. In one embodiment a first surface 154 of cavity 150 is congruent to surface 66B, having a terminating rim 158. A second surface 162 of cavity 150 comprises a mirror image of first surface 154, the mirror plane being orthogonal to axis 54, the second surface having an external terminating rim 166, and the two surfaces are connected together at their congruent external rims, rims 166 and 158. Second surface 162 also comprises circular opening 182, so that the surface terminates in an internal circular rim 170 surrounding opening 182.

It will be understood that the description above of the shape of surfaces 154 and 162 is purely by way of example. Other surface shapes providing similar properties to those described herein for cavity 150 will be familiar to those having ordinary skill in the art, and all such shapes for surfaces 154 and 162 are assumed to be comprised within the scope of the present invention.

Cavity 150 is coupled to cavity 14E by sealing rim 170 to rim 186, so forming a coupling iris 190 between the two cavities, the coupled cavities forming dual cavity system 128. In an embodiment, cavity 150 is dimensioned to resonate at approximately the same resonant frequency as cavity 14E, when excited in a TM₀₁₀ mode. By virtue of the two cavities being coupled together, the fundamental TM modes of the two cavities hybridize to form two new TM modes, and the frequency difference between the modes is set by the coupling between the modes.

In a disclosed embodiment the frequency difference between the modes is less than the coupling between the modes. In an alternative embodiment the frequency difference is of the same order of magnitude as the coupling.

Because the two cavities have approximately the same resonant frequency, the new modes approximately equally spread out over the two cavities, and the electric field of each mode at the region of transmon 12 is substantial, although it may or may not be the maximum field of the mode.

Thus, apparatus 410, being formed as a dual cavity system, has a larger capacity to encode quantum information than a single cavity system. If the single cavity system is used to encode one computational qubit, the dual cavity system may be used to encode two computational qubits in the two modes.

Furthermore, since cavity 150 does not require a plane surface such as surface 86 of cavity 14E, the filling factor of cavity 150 may be configured to be smaller than that of cavity 14E. Consequently the Q of cavity 150 may be larger than that of cavity 14E, so that the Q of dual cavity systems such as system 128 may be larger than that of a single cavity system such as system 28D.

The larger Q increases the time period during which apparatus 410 is able to operate as a computational qubit.

In some embodiments cavity 150 may have an aperture 152 provided in surface 154, and the aperture may be used to characterize dual cavity system 128, as is described above for cavity 14A. In other embodiments aperture 152 is not present.

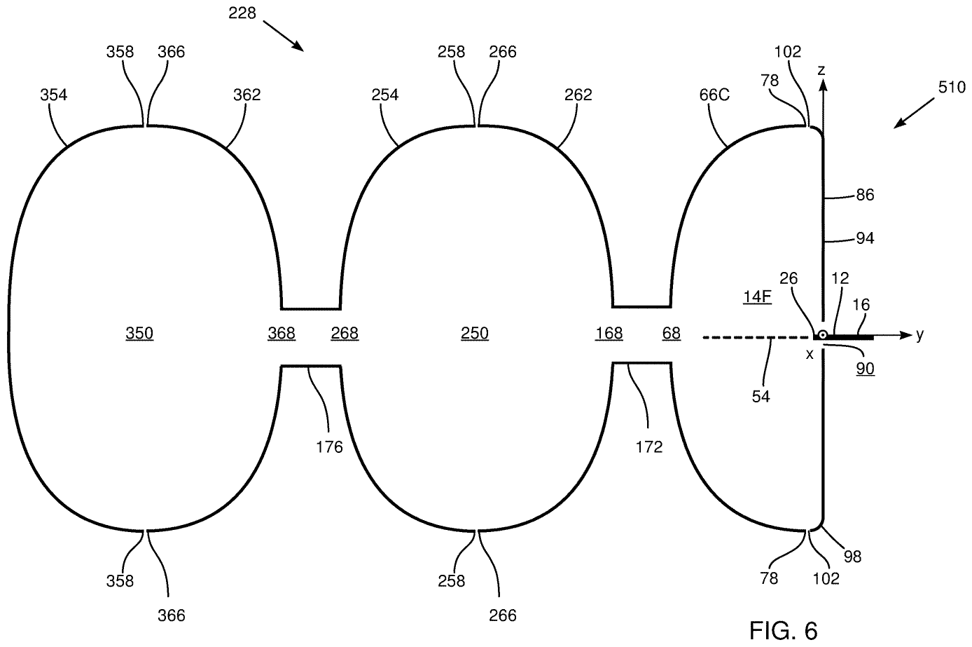

FIG. 6 is a schematic sectional illustration of elements of an apparatus 510 for quantum computing, according to an alternative embodiment of the present invention. Apart from the differences described below, the operation of apparatus 510 is generally similar to that of apparatus 310 (FIG. 4), and elements indicated by the same reference numerals in apparatus 310 and apparatus 510 are generally similar in construction and in operation.

FIG. 6 shows cavity surfaces and transmon 12 of apparatus 510, as they appear when cut by the yz plane.

In contrast to apparatus 310, and as illustrated in the figure, apparatus 510 comprises three coupled cavities. The three coupled cavities comprise a first cavity 14F, which except as described below is substantially similar to cavity 14D (FIG. 4), a second cavity 250, and a third cavity 350. The three coupled cavities form a multiple cavity system 228.

In a disclosed embodiment cavity 250 and cavity 350 are generally similar to cavity 150. Thus, surfaces 254 and 262, and surfaces 354 and 362, are respectively similar to surfaces 154 and 162, and rims 258 and 266, and rims 358 and 366, are respectively similar to rims 158 and 166.

The description above of the shape of surfaces 254 and 262, and of surfaces 354 and 362, is purely by way of example. Other surface shapes providing similar properties to those described herein for cavities 250 and 350 will be familiar to those having ordinary skill in the art, and all such shapes for the surfaces of these cavities are assumed to be comprised within the scope of the present invention.

An aperture 68 is formed in a region of surface 66C surrounding axis 54, and an aperture 168 is formed in a region of surface 262 surrounding the axis. A waveguide 172 connects the two apertures, so coupling cavity 14F to cavity 250. Cavity 250 is coupled to cavity 350 in a similar manner, by configuring a waveguide 176 to connect an aperture 268 in surface 254 to an aperture 368 in surface 362, the two apertures surrounding axis 54.

Cavities 250 and 350 are dimensioned to resonate at approximately the same resonant frequency as cavity 14F, when excited in a TM₀₁₀ mode. Because the three cavities are coupled together, the fundamental TM modes of the three cavities hybridize to form three new TM modes, and the frequency difference between the modes is set by the coupling between the cavities, i.e., by the dimensions of waveguides 172 and 176.

As for the dual cavity system described above, in an embodiment of the three cavity system of apparatus 510, the frequency difference is less than the coupling between the modes. Alternatively, the frequency difference is of the same order of magnitude as the coupling.

The new modes are approximately equally spread over the three cavities, and the electric field of each mode is, as for the dual cavity system, substantial at the region of transmon 12, although not necessarily being the maximum field of the mode.

By being able to support three fundamental TM modes, apparatus 510, a three-cavity system, has a larger capacity to encode quantum information than a single cavity system. If the single cavity system is used to encode one computational qubit, the three-cavity system may be used to encode three computational qubits in the three modes.

Neither cavity 250 nor cavity 350 have a planar surface such as surface 86 of cavity 14F, so that the Q of cavities 250 and 350 may be higher than the Q of cavity 14F. The Q of multiple cavity 228 may consequently be higher than that of a single cavity system or of a dual cavity system.

From consideration of the examples provided above having more than one cavity, it will be understood that the number of fundamental modes that a cavity system is able to support is equal to the number of cavities in the system, i.e., the cavity cardinality of the system. In addition, the number of different qubits that may be encoded is equal to the cavity cardinality of the system. I.e., N cavities support N fundamental modes, and enable N computational qubits to be encoded, where N is a natural number.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. Apparatus for quantum computing, comprising:
a superconducting shell having a first surface of rotation about a central axis, wherein all points on the first surface have a finite radius of curvature, and a second surface of rotation, different from the first surface of rotation, about the central axis, the first surface terminating in a first rim, the second surface having an aperture and terminating in a second rim congruent to the first rim, the first rim and the second rim being sealed together to enclose a microwave cavity within the shell; and
a superconducting qubit formed on a substrate, which is mounted so that a portion of the substrate penetrates through the aperture, thereby coupling the superconducting qubit to the microwave cavity.

2. (canceled)

3. The apparatus according to claim 1, wherein a tangent plane to a point on the first rim is parallel to the central axis.

4.-7. (canceled)

8. The apparatus according to claim 1, and comprising a further aperture inserted into the first surface of rotation.

9. The apparatus according to claim 1, wherein the first surface of rotation and the second surface of rotation are shaped and dimensioned so that the microwave cavity resonates at a selected microwave frequency, and so that an electric field of microwaves resonating at the selected microwave frequency is a maximum in proximity to the aperture.

10. (canceled)

11. The apparatus according to claim 1, wherein the aperture lies on the central axis.

12. The apparatus according to claim 1, wherein an edge of the substrate lies between a first plane defined by the first rim and second plane, normal to the central axis, containing a point where the aperture cuts the central axis.

13. The apparatus according to claim 1, wherein at least a portion of the second surface is planar, so that all points on the at least portion have an infinite radius of curvature.

14. (canceled)

15. The apparatus according to claim 1, wherein at least a portion of the second surface is curved, so that all points on the at least portion have a finite radius of curvature.

16.-19. (canceled)

20. Apparatus for quantum computing, comprising:
a superconducting shell having a first surface of rotation about a central axis, and a second surface of rotation, different from the first surface of rotation, about the central axis, the first surface terminating in a first rim, the second surface having an aperture and terminating in a second rim congruent to the first rim, the first rim and the second rim being sealed together to enclose a microwave cavity within the shell; and
a superconducting qubit formed on a substrate, which is mounted so that a portion of the substrate penetrates through the aperture, thereby coupling the superconducting qubit to the microwave cavity,
wherein the first surface has a first opening centered on the central axis, and wherein the superconducting shell further comprises:
at least one more microwave cavity therein, the at least one more microwave cavity comprising a given cavity having a second opening connected to the first opening so as to couple the microwave cavity and the at least one more microwave cavity.

21. The apparatus according to claim 20, wherein the microwave cavity and the at least one more microwave cavity are configured to resonate in a number of fundamental transverse magnetic modes equal to a cardinality of the microwave cavity and the at least one more microwave cavity.

22. The apparatus according to claim 21, wherein a difference in frequencies of resonance of the fundamental transverse magnetic modes is less than a coupling between the modes.

23. The apparatus according to claim 20, wherein the superconducting qubit is configured to encode a number of computational qubits to the microwave cavity and the at least one more microwave cavity, wherein the number of computational qubits is equal to a cardinality of the microwave cavity and the at least one more microwave cavity.

24. A method for quantum computing, comprising:
providing a superconducting shell;
forming within the superconducting shell a first surface of rotation about a central axis wherein all points on the first surface have a finite radius of curvature, and a second surface of rotation, different from the first surface of rotation, about the central axis, the first surface terminating in a first rim, the second surface having an aperture and terminating in a second rim congruent to the first rim, the first rim and the second rim being sealed together to enclose a microwave cavity within the shell;
forming a superconducting qubit on a substrate; and
mounting the substrate so that a portion thereof penetrates through the aperture, thereby coupling the superconducting qubit to the microwave cavity.

25. (canceled)

26. The method according to claim 24, wherein a tangent plane to a point on the first rim is parallel to the central axis.

27.-30. (canceled)

31. The method according to claim 24, and comprising inserting a further aperture into the first surface of rotation.

32. The method according to claim 24, wherein the first surface of rotation and the second surface of rotation are shaped and dimensioned so that the microwave cavity resonates at a selected microwave frequency, and so that an electric field of microwaves resonating at the selected microwave frequency is a maximum in proximity to the aperture.

33. (canceled)

34. The method according to claim 24, wherein the aperture lies on the central axis.

35. The method according to claim 24, wherein an edge of the substrate lies between a first plane defined by the first rim and second plane, normal to the central axis, containing a point where the aperture cuts the central axis.

36. The method according to claim 24, wherein at least a portion of the second surface is planar, so that all points on the at least portion have an infinite radius of curvature.

37. (canceled)

38. The method according to claim 24, wherein at least a portion of the second surface is curved, so that all points on the at least portion have a finite radius of curvature.

39.-41. (canceled)
